(19) United States
(12) Patent Application Publication
(10) Pub. No.: US 2004/0253839 A1
(43) Pub. Date: Dec. 16, 2004

(54) Semiconductor manufacturing apparatus and heat treatment method

(75) Inventors: Masahiro Shimizu, Nirasaki-Shi (JP); Yusaku Kashiwagi, Nirasaki-Shi (JP); Gishi Chung, Nirasaki-Shi (JP); Yoshihide Tada, Nirasaki-Shi (JP); Genji Nakamura, Nirasaki-Shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 10/864,596

(22) Filed: Jun. 10, 2004

(30) Foreign Application Priority Data
Jun. 11, 2003 (JP) 2003-166809
Jun. 18, 2003 (JP) 2003-173434

(51) Int. Cl. H01L 21/26; H01L 21/42; H01L 21/477

(52) U.S. Cl. 438/795

(57) ABSTRACT

A heat treatment apparatus selectively heats an object material to be heated so as to achieve energy saving and low-temperature heating. A light source irradiates a light onto a heating material through a transparent window of a process chamber. A controller controls an output of the light source. The heating material is a material to form a layer formed in a wiring process after a semiconductor structure is formed in a semiconductor manufacturing process. The light irradiated by the light source has a specific wavelength at which an optical absorption factor of the heating material is larger than at other wavelengths. The transparent window is formed of a material that passes therethrough the light having the specific wavelength.

### BACKGROUND OF THE INVENTION

1. Field of the Invention

The present invention generally relates to semiconductor manufacturing techniques and, more particularly, to a semiconductor manufacturing apparatus and a heat treatment method for modifying properties of a thin film formed on a substrate by applying a heat treatment onto the thin film.

2. Description of the Related Art

In a manufacturing process of semiconductor products, various thin films are formed on substrates, such as a silicon wafer. There is a case in which a material property modification is performed on such a thin film for acquiring desired properties by applying a heat treatment. Especially, with recent progress in increasing density and functions of semiconductor products, the material property modification of various thin films has become important.

As a conventional example of heat treatment for the material property modification, there is suggested a laser anneal. The laser anneal is a technique to heat a substrate or a thin film to be subjected to a heat treatment by irradiating a laser light and then cool the substrate or the thin film so as to acquire desired properties. However, the laser anneal technique has not been in practical use except for laser doping, and has been ended up at an idea stage.

In the above-mentioned laser anneal technique, there is an idea of melting and solidifying an object material to be property-modified (a material forming a thin film, etc.) but a technology to control a solidification rate when solidifying a melted material has not been suggested. According to the conventional laser anneal technique, a melted material is solidified at a solidification rate that is determined according to a heat transfer environment in hardware of a laser anneal apparatus (heat treatment apparatus). For this reason, the object material after being solidified becomes nothing but an amorphous or a polycrystal. As mentioned above, in the conventional laser anneal technique, cooling of an object material after heating is performed merely by natural cooling, and has not reached to a level to control intentionally a state of the object material.

Moreover, according to a heating method like radiation heating by laser light irradiation, if the light for heating has a wavelength at which the object material to be heated has an excellent optical absorption characteristic, the object material can be efficiently heated by radiation. However, in the conventional laser anneal technique, there is no example found that refers to a radiation heating design in consideration of a relationship between an optical absorption characteristic of a material to be heated and a wavelength of a light used for radiation heating.

The following patent documents disclose conventional heat treatment techniques such as mentioned above.

1) Japanese Laid-Open Patent Application No. 5-275336

2) Japanese Laid-Open Patent Application No. 7-202208

3) Japanese Laid-Open Patent Application No. 9-82662

4) Japanese Laid-Open Patent Application No. 2001-102593

Conventionally, when performing a material property modification on a thin film formed on a wafer using a semiconductor device manufacturing apparatus such as a heat treatment apparatus, it is necessary to heat an entire chamber of the apparatus and thus an entire wafer placed in the chamber, which condition causes the following problems.

1) Conventional heat treatment apparatuses has a low energy efficiency in heat treatment since a entire wafer or an entire apparatus is heated, and, thus, it is necessary to take measures for energy saving. That is, since heating is not applied solely to an object material (a part to be heated), whole energy consumption is large even though energy actually supplied to the object material is small.

2) Structural materials used for devices have been changed every year, and materials having a low heat resistance have become used. Accordingly, it is necessary to decrease a process temperature. That is, since heating is not applied solely to an object material (a part to be heated), a temperature of heating a wafer is dependent on a highest process temperature, which prevents the heat treatment temperature from being a lower temperature.

3) A solidification rate cannot be control since an object material cannot be cooled at a desired cooling rate after being melted. Therefore, the object material after solidification cannot be in a desired state.

### SUMMARY OF THE INVENTION

It is a general object of the present invention to provide an improved and useful heat treatment apparatus and method in which the above-mentioned problems are eliminated.

A more specific object of the present invention is to provide a heat treatment apparatus and method which can selectively heat an object material to be heated so as to achieve energy saving and low-temperature heating in the heat treatment apparatus.

Another object of the present invention is to provide a heat treatment apparatus and method which can control a temperature from which an object material is started to be cooled before the object material is melted so as to intentionally modify properties of the object material.

In order to achieve the above-mentioned objects, there is provided according to one aspect of the present invention a semiconductor manufacturing apparatus for applying a heat treatment to a heating material to be heated by radiation-heating by irradiating a light onto the processing object, the semiconductor manufacturing apparatus comprising: a process chamber configured to accommodate a processing object containing the heating material; a transparent window provided as a part of an outer wall of the process chamber; a light source that generates the light so as to irradiate the light onto the heating material through the transparent window; and a controller that controls an output of the light source, wherein the heating material is a material to form a layer formed in a wiring process after a semiconductor structure is formed in a semiconductor manufacturing process; the light irradiated by the light source has a specific wavelength at which an optical absorption factor of the heating material is larger than at other wavelengths; and the transparent window is formed of a material that passes therethrough the light having the specific wavelength.

According to the present invention, in a BEOL (back end of line) structure in a transistor structure, material modification of the heating material to be heated can be achieved by selectively heating and cooling the heating material. Additionally, because the heating is selective heating, energy consumed by heating can be reduced, which achieves an energy saving and low-temperature heating of the semiconductor manufacturing apparatus including the heat treatment apparatus.

In the above-mentioned semiconductor manufacturing apparatus, the light source may be a laser source that outputs a laser light, and the semiconductor manufacturing apparatus may further comprise an optical system that direct the laser light so that the laser light is irradiated onto the heating material in a linear form.

The laser source may be an infrared laser, and the heating material may be a low-dielectric film formed in the wiring process of the semiconductor manufacturing process. The infrared laser may be a CO₂ laser, and the transparent window may be formed of germanium. Alternatively, the light source may be an infrared lamp that outputs an infrared light, and the heating material may be a low-dielectric film formed in the wiring process of the semiconductor process. Further, the laser source may be an ultraviolet laser, and the heating material may be a barrier metal film formed in the wiring process of the semiconductor manufacturing process. The ultraviolet laser may be an excimer laser, and the transparent window is formed of calcium fluoride. Alternatively, the light source may be an ultraviolet lamp that outputs an ultraviolet light, and the heating material may be a barrier metal film formed in the wiring process of the semiconductor manufacturing process.

Additionally, there is provided according to another aspect of the present invention a heat treatment method used for a heat treatment applicable to a film formed in a wiring process of a semiconductor manufacturing process, the heat treatment method comprising: irradiating a light having a wavelength that corresponds to an optical absorption wavelength of the film formed in the wiring process of the semiconductor manufacturing process so as to selectively heat the film with respect to surrounding parts; and cooling the heated film by heat transfer to the surrounding parts by controlling an intensity of the light irradiated onto the film.

In the above-mentioned heat treatment method, the film may be a low-dielectric material having an Si—O bond, the light may be a CO₂ laser light, and a dielectric constant and a mechanical strength of the lo low-dielectric film may be varied by selectively heating the low-dielectric film. The low-dielectric film may be an SiOCH film. Alternatively, the film may be a barrier metal film formed between a low-dielectric film and a electrically conductive layer, the light may be an ultraviolet laser light, and the barrier metal film may be selectively heated, thereby improving adhesion between the barrier metal film and the low-dielectric film. The barrier metal film may be a TaN film or a Ta film, and the ultraviolet laser light is an excimer laser light.

Additionally, there is provided according to another aspect of the present invention a semiconductor manufacturing apparatus for applying a heat treatment to a heating material to be heated by radiation-heating by irradiating a light onto the processing object, the semiconductor manufacturing apparatus comprising: a process chamber configured to accommodate a processing object containing the heating material; a transparent window provided as a part of an outer wall of the process chamber; a light source that generates the light so as to irradiate the light onto the heating material through the transparent window; and a controller that controls an output of the light source, wherein the light irradiated by the light source has a specific wavelength at which an optical absorption factor of the heating material is larger than at other wavelengths; and the transparent window is formed of a material that does not absorb the light having the specific wavelength.

According to the above-mentioned invention, material modification of the heating material to be heated can be achieved by selectively heating the heating material and thereafter cooling the selectively heated hating material. Additionally, because the heating is selective heating, energy consumed by heating can be reduced, which achieves an energy saving and low-temperature heating of the semiconductor manufacturing apparatus including the heat treatment apparatus. Further, material modification of the heating material can be achieved by selectively heating and melting the heating material alone, and controlling a solidification rate of the melted heating material.

In the above-mentioned semiconductor manufacturing apparatus, the light source may be a laser source which outputs a laser light, and the semiconductor manufacturing apparatus may further comprise an optical system that direct the laser light so that the laser light is irradiated onto the heating material in a linear form. The laser source may be an infrared laser, and the heating material may be a silicon oxide film formed in an initial process of a semiconductor manufacturing process. The infrared laser may be a CO₂ laser, and the transparent window may be formed of germanium. Alternatively, the light source may be an infrared lamp that outputs an infrared light, and the heating material may be a silicon oxide film formed in an initial process of a semiconductor manufacturing process. The transparent window may be formed of Al₂O₃.

Additionally, there is provided according to another aspect of the present invention a heat treatment method used for semiconductor manufacturing, comprising: irradiating a light having a wavelength that corresponds to an optical absorption wavelength of a heating material to be heated and formed in a wiring process of a semiconductor manufacturing process so as to selectively heat the heating object with respect to surrounding parts; and cooling the heated heating material by heat transfer to the surrounding parts by controlling an intensity of the light irradiated onto the heating material.

In the above-mentioned heat treatment method, the heating material may be a silicon oxide film, and the light may be a CO₂ laser light. The heating material may be a silicon oxide film, and the light may be an infrared light output from an infrared lamp. The heating material may be melted by being selectively heated, and, in a subsequent cooling process, the melted heating material may be rapidly cooled so that crystallization and crystal growth of the heating material are suppressed. The heating material may be melted by being selectively heated, and, in a subsequent cooling process, the melted heating material may be rapidly cooled so that elements contained in the heating material segregate during solidification of the melted heating material.

Other objects, features and advantages of the present invention will become more apparent from the following detailed description when read in conjunction with the accompanying drawings.

### BRIEF DESCRIPTION OF THE DRAWINGS

FIG. 1 is a graph showing a temperature rise in a layer structure when a CO₂ laser is irradiated onto the layer structure in which a low-dielectric film is formed on a silicon substrate;

FIG. 2 is an illustrative cross-sectional view of a heat treatment apparatus according to a first embodiment of the present invention;

FIG. 3 is an illustrative plan view of the heat treatment apparatus shown in FIG. 2;

FIG. 4 is an illustrative cross-sectional view of a heat treatment apparatus according to a second embodiment of the present invention;

FIG. 5 is a graph showing a relationship between absorption factor and V3D3 film;

FIGS. 6A through 6D are illustrations showing results of calculation of a melting time when a CO₂ laser is irradiated onto a low-dielectric film;

FIGS. 7A through 7D are illustrations showing results of calculation of a melting time when an ultraviolet laser is projected onto a barrier metal film via a low-dielectric film;

FIG. 8 is a graph showing a temperature rise in a layer structure when a CO₂ laser is irradiated onto the layer structure in which an SC—Ox film is formed on a silicon substrate;

FIGS. 9A through 9D are illustrations showing results of calculation of a melting time when a CO₂ laser is irradiated onto a screen oxide film; and

FIGS. 10A through 10D are illustrations showing results of calculation of a melting time when a CO₂ laser is irradiated onto a gate oxide film.

### DETAILED DESCRIPTION OF THE PREFERRED EMBODIMENT

A description will now be given of a principle of selective radiation heating according to the present invention.

In a case where a material property modification is performed according to the selective radiation heating, a selective radiation heating design of a multi-layer structure must be performed in a wafer treatment process in accordance with a radiation energy absorption characteristic of a material to be property-modified. That is, it is examined whether conditions, which permit the selective radiation heating being applied to an object material, are satisfied. As a condition which permits the selective radiation heating being applied, (1) it is necessary that an inverse number of an absorption length (an inverse number of an absorption coefficient: 1/alpha) of an object material to be property-modified is greater than or substantially equal to a thickness of the object material (absorption length≧film thickness of object material). Additionally, (2) if the absorption length of the object material to be property-modified is smaller than the film thickness of the object material, a backing layer of the layer of the object material must have a material structure having a high-reflectance (for example, a reflectance of 95% or more).

A melting time of the object material is calculated according to a selective radiation heating design in view of the above-mentioned conditions (1) and (2) so as to confirm that the object material is first melted when a substrate (wafer) containing the object material layer is radiation-heated. When irradiating, for example, a laser light as a radiation-heating source, the object material layer can be selectively and adiabatically heated by radiation so as to be melted by irradiation of the laser light for only the above-mentioned melting time.

Here, a consideration is given to a relationship between an irradiation time of a light for radiation heating and a temperature rise of a substrate containing the object material layer.

When a heat flux q0 is applied to a semiinfinite body, a depth δ from a body surface and a temperature T(δ,t) at a time t can be represented by the following equation (1). It should be noted that, in the following equation (1), K represents a thermal conductivity, A represents an area, and Td represents a thermometric conductivity.

$$T ( δ \cdot t ) - Ti = \frac{2 q0}{KA} [ \sqrt{\frac{Td \cdot t}{π}} exp ( - \frac{{δ}^{2}}{4 T d t} ) - \frac{δ}{2} erf ( \frac{δ}{2 \sqrt{T d t}} ) ] \qquad Equation ( 1 )$$

Here the error function erf can be approximated by a quadratic function, and Ti is a room temperature, which can be ignored. Thus, the above equation (1) can be changed into the following equation (2).

$$\begin{matrix}T ( δ \cdot t ) = \frac{2 q 0}{KA} \{ \sqrt{\frac{Td \cdot t}{π}} exp ( - \frac{{δ}^{2}}{4 T d t} ) - \\ {\frac{δ}{2} [ 1 - \frac{1}{\sqrt{3}} ( \frac{δ}{2 \sqrt{T d t}} ) ]}^{2} \}\end{matrix} \qquad Equation ( 2 )$$

The temperature T(δ,t) can be calculated at any position from the body surface by giving a material structure and physical properties of the object material and a value of the heat flux.

As an example of the above-mentioned temperature calculation, an attempt was made to calculate a temperature rise in a layer structure having a V3D3 film formed on a silicon (Si) substrate by heating the layer structure by irradiation of a CO₂ laser.

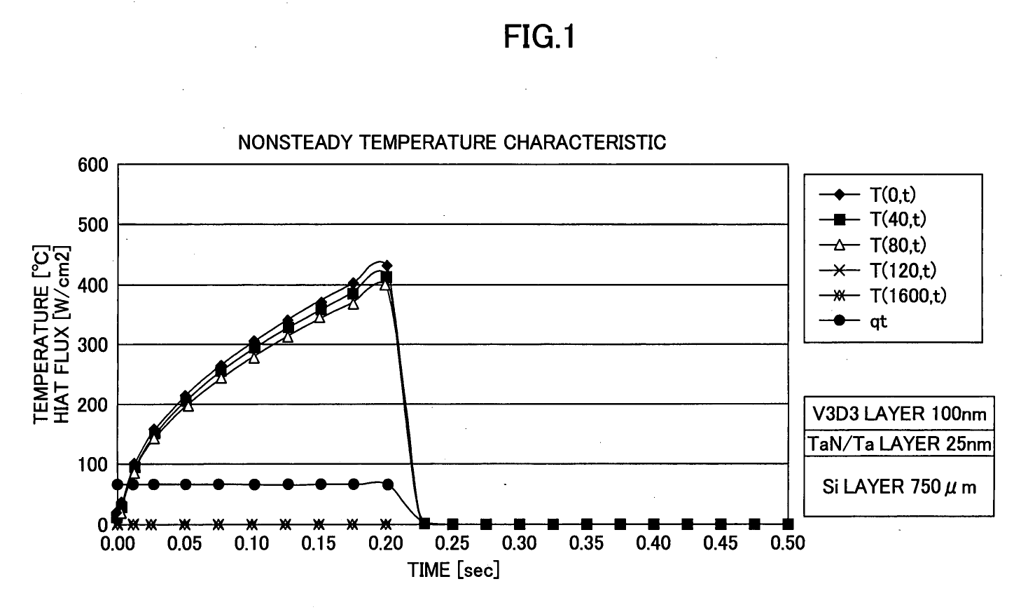

FIG. 1 is a graph showing the result of calculation. A thickness of the silicon substrate was set to 750 micrometers, and a thickness of the V3D3 film was set to 100 nm. In the graph of FIG. 1, T(0,t) represents a temperature of a surface of the V3D3 film, and T(40,t), T(80,t), T(120,t) and T(1600,t) represent temperatures at positions 40 nm, 80 nm, 120 nm and 1600 nm from the surface, respectively. Therefore, T(40,t) and T(80,t) are temperatures within the V3D3 film, T(120,t) is a temperature of the silicon substrate near a boundary, and T(1600,t) is a temperature at a position away from the boundary.

It can be appreciated from the graph of FIG. 1 that the temperatures fall rapidly immediately after the entire V3D3 layer exceeds the glass-transition temperature (for example, 300° C., 400° C.) at a point near the laser irradiation time exceeded 50 seconds. On the other hand, it is appreciated that the temperature T(1600,t), which represents the temperature of the silicon substrate, does not change from the room temperature. Therefore, in the example shown in FIG. 1, only three layers of the surface of the V3D3 layer can be selectively heated and melted while maintaining the silicon substrate as a base layer at a room temperature.

Here, a melting time of an object material can be calculated based on the nonsteady heat conduction of a semiinfinite body in consideration of a radiation characteristic and an absorption coefficient alpha and a film thickness of the material.

In the radiation characteristic, T=[(1-R)²*exp(−αd)]/[1-R²*exp(−2αd)] and R=[(n−1)²+k²]/[(n+1)²+k²] where T is a transmittance (nondimensional number), R is a reflectance (nondimensional number) and Abs is an absorptance (nondimensional number). Here, k is a coefficient of decrease of the material. Then, there is established between T, R and Abs a relationship Abs=1-T-R.

The temperature T(0,t) of a surface of an object material can be calculated according to the following equation (3) in accordance with a nonsteady heat conductance of a semiinfinite body, where F Abs is a heat flux per unit area.

$$T ( δ \cdot t ) = \frac{2 F \cdot Abs}{K} \sqrt{\frac{Td \cdot t}{π}} \qquad Equation ( 3 )$$

Accordingly, a time the surface temperature reaches a melting point can be obtained by the following equation (4), where Td is a thermal diffusion constant [cm²/sec].

$${t}_{m} = {( \frac{Tm \cdot K}{2 F \cdot Abs} )}^{2} \frac{π}{Td} \qquad Equation ( 4 )$$

Moreover, a time Tbt from melting a front surface until melting a bottom surface can be represented as Tbt=dρΔH/0.16F.Abs by applying a surface energy conservation law to a primary thermal conduction equation of a semiinfinite body, where ρ is a density of the object material and ΔH is a melting latent heat.

As mentioned above, the time t until the film of the object material melts can be obtained by t=tm+tbt. Based on the calculated value, a time until a film or layer of the object material to modified and the substrate or another film on which the object material is formed is obtained so as to confirm that the object material melts first. That is, if the object material first melts, the object material can be selectively heated to melt by radiation-heating the object material only for the time obtained by the calculation.

A description will now be given, with reference to the drawings, of embodiments of the present invention.

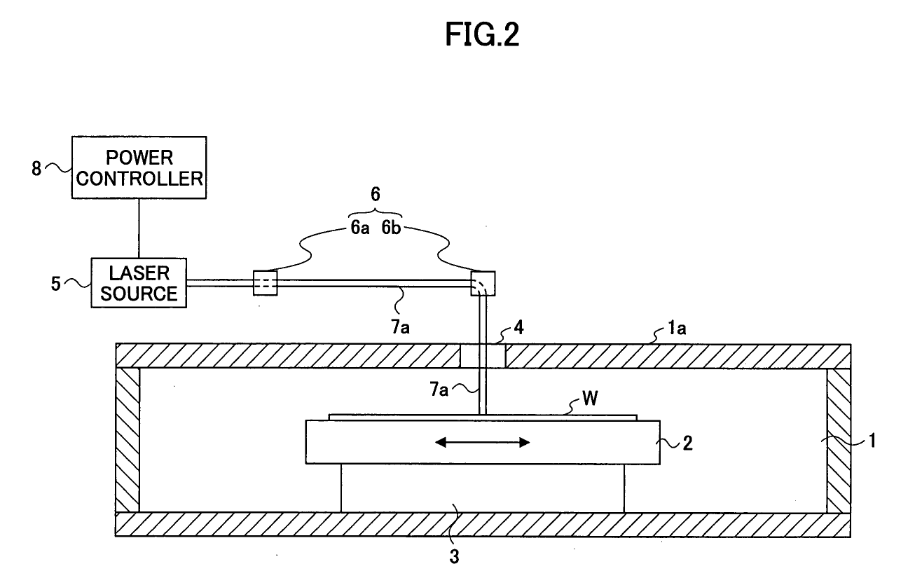

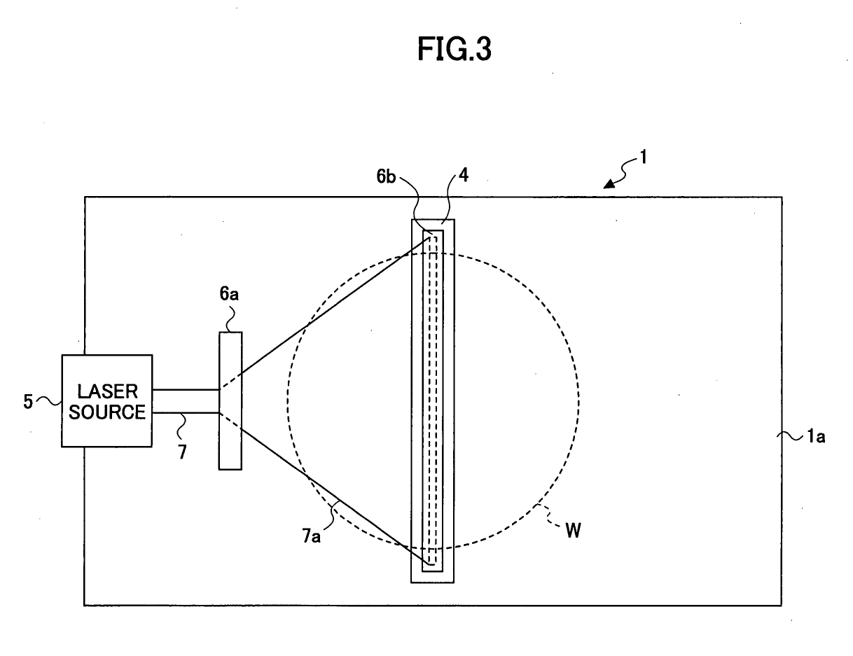

First, a description will be given, with reference to FIGS. 2 and 3, of a semiconductor manufacturing apparatus according to a first embodiment of the present invention. FIG. 2 is an illustration showing an outline of a heat treatment apparatus as the semiconductor manufacturing apparatus according to the first embodiment of the present invention. FIG. 3 is a plan view of the heat treatment apparatus shown in FIG. 2.

The heat treatment apparatus shown in FIG. 2 is a selective radiation-heating apparatus, which selectively heats a surface of a wafer W (a thin film formed on the surface) by irradiating a laser light onto the wafer W placed on a susceptor in a process chamber.

The susceptor 2 located in the process chamber 1 is movable in horizontal directions within the process chamber by a susceptor moving mechanism 3. The wafer W faces a ceiling wall 1a of the process chamber 1 in a state where the wafer W is placed on the susceptor 2. The walls of the process chamber 1 including the ceiling wall 1a are formed of a ceramic material such as aluminum oxide or aluminum nitride, and the interior of the process chamber 1 is isolated from a surrounding atmosphere. Since the isolated interior of the process chamber 1 may be controlled to be an atmosphere of vacuum or a specific gas which hardly absorbs a processing light so as to prevent the atmosphere from influencing the processing light. Descriptions of a gas introducing part and a gas evacuating pump will be omitted since known mechanisms can be used. Additionally, the same process can be applied to an optical system.

A transparent window 4 is provided as a part of the ceiling wall 1a in the center of the ceiling wall 1a of the process chamber 1. A laser source 5 is provided on the outer side of the process chamber 1 so as to project a laser beam into the interior of the process chamber 1 through an optical system 6 including a lens, a prism, etc. That is, the laser light 7 output from the laser source 5 is expanded by a lens 6a into a linear laser light 7a as shown in FIG. 3, and is directed to the transparent window 4 of the process chamber 1 after being deflected by 90 degrees by a prism or deflection reflection plate 6b.

Then, the laser light 7a passes the transparent window 4 and is projected onto the wafer W placed on the susceptor 2. The thin film formed on or near the front side of the wafer W is heated at a predetermined temperature by the laser light 7a. Here, the output of the laser source 5 is controlled by a power controller 8 so that the laser light 7a of a predetermined intensity is projected onto the wafer W. When the power controller 8 cuts off the output of the laser source 5, the heating of the wafer W is stopped, which results in cooling of the wafer W. Additionally, a cooling rate can be controlled by causing the laser source 5 to output the laser light with a small power without completely cutting off the laser source 5. Furthermore, it is possible that the power controller 8 also controls the intensity of the laser output to vary with passage of time.

The susceptor 2 is constituted so as to be movable stepwisely in a horizontal direction within the process chamber 1 by being driven by a susceptor moving mechanism 3 so that the wafer W is scanned by the linear laser light by sequentially moving a laser irradiated position on the wafer W. Thereby, the laser light 7a can be projected to the entire surface of the wafer W, which allows a heat treatment being applied on the entire surface of the wafer W. It should be noted that the susceptor moving mechanism 3 can be a well-known moving mechanism, and a description thereof will be omitted.

Here, the wavelength of the laser light 7 is selected according to an optical absorption wavelength of an object material to be heated (the wafer W or a thin film formed on the wafer W). For example, when applying a heat treatment (material modification) to a silicon oxide film formed on the wafer W, a carbon dioxide laser (CO₂ laser), which is an infrared laser having a wavelength of 9.6 μm to 10.6 μm. Therefore, the CO₂ laser is used as the laser source 5 in this embodiment. Since the transparent window used in a conventional heat treatment apparatus is made of molten quartz (penetration wave length of 0.4 μm-3.5 μm), the CO₂ laser of a wavelength of 9.6 μm-10.6 μm cannot pass through the conventional transparent window. Therefore, it is preferable to select germanium (Ge), which transmits a light having a wavelength of 2.5 μm-13 μm, as a material that can pass the CO₂ laser without absorbing the CO₂ laser.

However, the kind (wavelength) of the laser and the material of the transparent window 4 are not limited to the above-mentioned combination, and there may be various combinations of a wavelength which can selectively heat an object material to be heated and a material which can pass a light having the wavelength with a small loss.

As a material which can transmit a light having a wavelength longer than that of the conventional molten quartz, there is considered an infrared transparent crystal material such as alkaline fluoride, alkaline earth fluoride, a semiconductor material or an infrared transmissible glass.

For example, as alkaline fluoride, there are NaF, NaCl, KCl, KBr, KI, CsBr, CsI, etc. As alkaline earth fluoride, there are CaF₂, SrF₂, BaF₂, MgF₂, PbF₂, etc. As a semiconductor material, there are Ge, Si, GaAS, ZnS, ZnSe, CdTe, etc. As infrared permissible glass, there are charcogenide glass (Ge33As12S55), Corning 9754 (trademark), etc.

The infrared transmittance can be improved by applying an anti-reflection coating on a transparent window formed of one of the above-mentioned infrared transmissible crystal materials. For example, Ge or SiO₂ may be coated on both sides of a transparent window formed of Ge or Si. Moreover, ZnSe and ThF₄ may be coated on both sides of a transparent window formed of ZnSe.

Moreover, a large bending stress may be generated in the transparent window of the process chamber, and the above-mentioned material alone may not withstand such a bending stress. Thus, the transparent window may be formed with two parts, one being a lattice-like frame part having a strength to withstand the bending stress and the other being a small area part divided by the frame part. The frame part may be formed of, for example, transparent ceramics having a relatively large strength, and the small area part may be formed of one of the above-mentioned infrared transparent crystal material alone or with the anti-reflection coating. For example, the frame part is formed of alumina (Al₂O₃), single-crystal alumina or sapphire, and the small area part is formed of BaF₂. Or the small area part may be formed by a ZnSe substrate with ZnSe and ThF₄ coating on both sides.

It should be noted that although the heat treatment apparatus according to the above-mentioned embodiment uses an infrared laser light to heat the wafer W, an infrared lamp may be used instead of the infrared laser. Moreover, the kind of laser is not limited to the infrared laser, and an ultraviolet laser may be suitable depending on the object material to be heated. Moreover, an ultraviolet lamp may be used instead of the ultraviolet laser.

As mentioned above, in the heat treatment apparatus according to the present embodiment, a light having a wavelength suitable for an optical absorption wavelength of an object material to be heated is irradiated so as to efficiently heat the object material. Moreover, since a material which hardly absorbs a light is selected for the material of the transparent window through which a light for heating passes in accordance with the wavelength of the light, an energy loss of the light when passing through the transparent window is reduced, which permits an efficient heat treatment and reduction in an amount of energy consumed in the operation of the heat treatment apparatus.

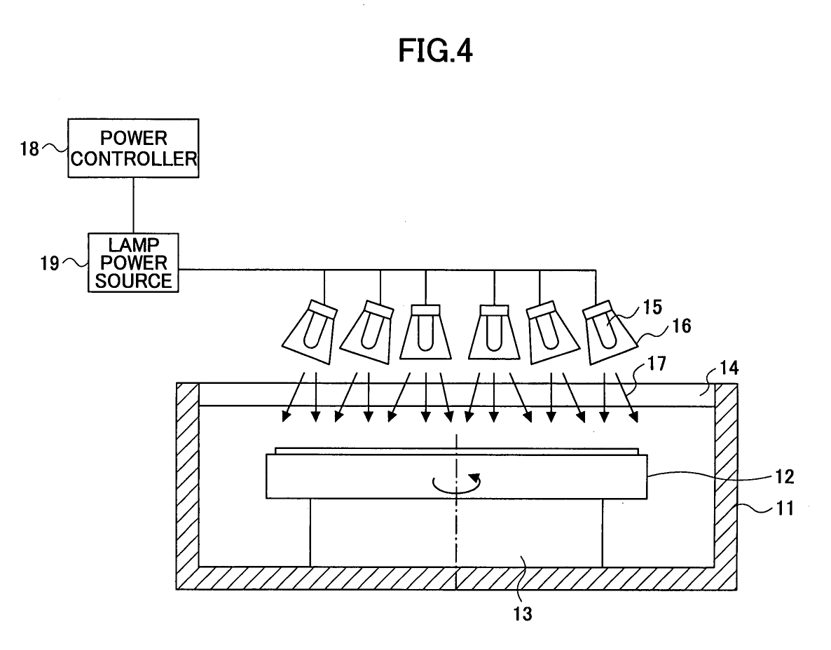

A description will now be given, with reference to FIG. 4, of a heat treatment apparatus as a semiconductor manufacturing apparatus according to a second embodiment of the present invention. FIG. 4 is a cross-sectional view of the heat treatment apparatus according to the second embodiment of the present invention.

The heat treatment apparatus shown in FIG. 4 is a selective radiation heating apparatus, which selectively heats a wafer surface (a film formed on a surface) by projecting a lamp light onto a wafer W placed on a susceptor in the process chamber.

The susceptor 12 arranged in the process chamber 11 is constituted so that the susceptor 12 is rotatable in a horizontal plane by being driven by a susceptor rotating mechanism 13 within the process chamber 11. The wafer W faces a ceiling wall of the process chamber in a state where the wafer W is placed on the susceptor 12. The walls of the process chamber 11 are formed of ceramics material such as aluminum oxide or aluminum nitride, and the interior of the process chamber 11 is isolated from a surrounding atmosphere.

The ceiling wall of the process chamber 1 is a transparent window 14 formed of, for example, alumina (Al₂O₃). A plurality of lamps 15 are provided outside the process chamber 11 so as to project lamp lights into the interior of the process chamber 11 through the transparent window 14. That is, the lamp light 17 output from the lamps 15 is directed toward the transparent window 14 of the process chamber 11 by reflectors 16 provided around the respective lamps 15.

The lamp light 17 is projected onto the waver W placed on the susceptor 12 by passing through the transparent window 14. The surface of the wafer W or a film formed near the surface is heated at a predetermined temperature by the lamp light 17. Here, an output of a lamp power source 19 is controlled by a power controller 18 so that the lamp light having a predetermined intensity is projected onto the wafer W. When the power controller 18 controls the output of the lamp power source 19 to be cut off, the heating of the wafer is stopped and the thin film of the wafer W is cooled. Additionally, a cooling rate can be controlled by causing the lamp power source 19 to output the lamp light with a small power without completely cutting off the output of the lamp power source 19. Furthermore, it is possible that the power controller 18 also controls the intensity of the lamp output to vary with passage of time.

The susceptor 12 is rotatable by being driven by a susceptor rotating mechanism 13 within the process chamber 11 so that the wafer W is uniformly irradiated by the lamp light. Thereby, the entire surface of the wafer W can be heat-treated uniformly. It should be noted that the susceptor rotating mechanism 13 can be achieved by a known rotating mechanism, and a description thereof will be omitted.

Here, the wavelength of the lamp light 17 is selected according to the optical absorption wavelength of an object material to be heated (the wafer W or a thin film formed on the wafer). For example, when applying a heat treatment (material modification) to a silicon oxide film formed on the wafer W, a ceramic-coating lamp of a wavelength of 2 μm-11 μm is suitable. In such a case, it is preferable to select alumina (Al₂O₃) , which passes a light of a wavelength of 0.15 μm to 6.0 μm, as a material that hardly absorbs the lamp light for the transparent window 14 through which the lamp light 17 passes. However, the kind (wavelength) of the lamp and the material of the transparent window 14 are not limited to the above-mentioned combination, and there may be various combinations of a wavelength which can selectively heat an object material to be heated and a material which can pass a light having the wavelength with a small loss.

A description will now be given of an example of modifying a material by a heat treatment of a thin film using the above-mentioned heat treatment apparatus.

1) Example of modifying a material by heat treatment of a low-dielectric film while maintaining a surrounding area at a low temperature:

A wiring process to form a wiring layer of a conductive metal after forming a transistor structure on a wafer is generally referred to as BEOL (Back End of Line). In the BEOL, since a transistor structure has been formed before a heat treatment, it is preferable to heat only the object material to be heated while maintaining other materials at a relatively low temperature so that the transistor structure is not influenced by the heat treatment. Moreover, with the layer structure (referred to as a BEOL structure) formed in the BEOL, in order to attain high-speed operation of a transistor, an attempt has been made to form an interlayer insulating layer by a low-dielectric material (Low-k material) or form a wiring layer by a low-resistance material. Further, there is demand for a comprehensive improvement in the quality of the BEOL structure such as improving a mechanical strength or adherence of a structure formed by using the above-mentioned materials.

Accordingly, various kinds of low-k material and various kinds of wiring material are investigated so as to develop a process of reducing a circuit constant RC in the BEOL structure. In order to reduce the circuit constant RC, an effect of reducing C by a low-k material of an interlayer insulating layer is larger than an effect of reducing R by Cu as a wiring bulk material and TaN as a wiring barrier metal material.

Thus, in the material development of an interlayer insulating layer, although a low-dielectric characteristic of the material itself is required first, it has been suggested to reduce the dielectric characteristic by decreasing a density of the low-k material. Here, a decrease in the density of the interlayer insulating material results in a decrease in the mechanical strength of the interlayer insulating layer and also a decrease in adherence with a wiring material. For this reason, it is preferable to improve the mechanical strength and also improve adherence with the wiring material by applying a heat treatment to the interlayer insulating layer.

Therefore, there is a demand for applying a heat treatment to the interlayer insulating layer. However, since the interlayer insulating layer is a layer formed on a transistor structure previously formed in an FEOL (Front End of Line) process, it is required to selectively heat only the interlayer insulating layer while maintaining parts surrounding the interlayer insulating layer at a low temperature so that the transistor structure is prevented from being destroyed.

Although many kinds of low-k materials must be tried to check possibility of use when specifying a material suitable for the interlayer insulating layer, it is required to try the modification of the material to a suitable material by applying a heat treatment to the material. Generally, a degree of modification is larger as a heat treatment temperature is higher. That is, higher the processing temperature, higher the possibility of achieving a preferable material modification. However, in order to prevent the transistor structure, which is formed in the FEOL, from being influenced as mentioned above, it has been said that a heat treatment at a high temperature is not permitted in the BEOL process. That is, in the conventional semiconductor manufacturing apparatus (heat treatment apparatus), since the heating method of heating the entire process chamber or the entire wafer is used so as to heat the object material on the wafer, parts that surrounding the interlayer insulating layer as the object material are heated simultaneously, which results in an insufficient modification of the interlayer insulating layer.

Thus, in the present embodiment, the interlayer insulating layer is modified so as to have a desired characteristic by selectively heating the interlayer insulating layer using the heat treatment apparatus according to the present invention.

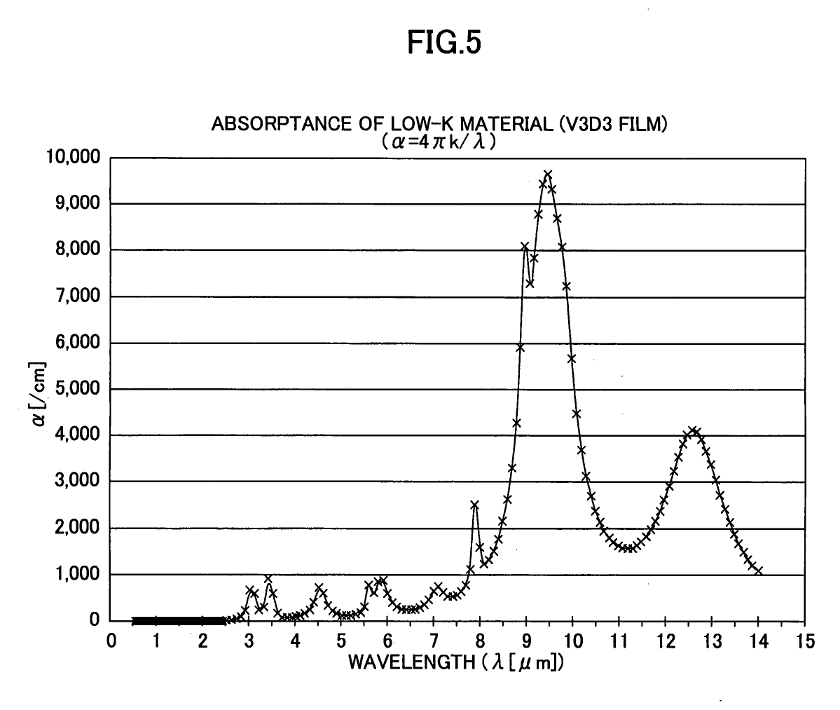

An SiOCH film is used in many cases as a siloxane base low-dielectric material (low-k material) to form the interlayer insulating material. The SiOCH film has an Si—O bond in the material structure thereof, and there is a wavelength at which the absorption factor starts to rapidly increase. FIG. 5 is a graph which shows an absorption coefficient alpha of for example, V3D3V film. Since it has the Si—O bond, it is appreciated that the absorption factor a sharply increases between the wavelengths of 8 μm and 10.5 μm.

Thus, if the V3D3 film can be radiation-heated by irradiating a light of a wavelength within a range where the absorption factor increases, the V3D3 film alone can be selectively heated. The absorption factor α of the V3D3 film has a peak value near the wavelength of 9.5 μm, which is close to the wavelength (9.6-10.6 μm) of a CO₂ laser which is an infrared laser.

Therefore, by using a CO₂ laser for the laser source 5 of the heat treatment apparatus shown in FIG. 2, the V3D3 film, which is a low-k film in the BEOL structure, can be selectively heated by irradiating the CO₂ laser. In such a case, although a TaN film or a Ta film is formed as a barrier metal, for example, under the V3D3 film which is a low-k film and a Cu film of a wiring layer is formed under the barrier metal, the absorption factors of those films with respect to the CO₂ laser is much smaller than the absorption factor of the V3D3, which results in selective and efficient heating so that the V3D3 film alone is selectively and efficiently heated.

After the V3D3 film reaches a predetermined temperature, the V3D3 is cooled by decreasing a laser irradiation energy of the CO₂ laser. Here, the cooling can be performed at a high-cooling rate by stopping the output of the CO₂ laser. That is, since only the V3D3 film is selectively heated, parts surrounding the V3D3 film are maintained at a low temperature, and the heat of the V3D3 film can rapidly diffuse into a surrounding area, the V3D3 film alone can be rapidly cooled. On the other hand, the cooling rate can be decreased by cooling the V3D3 film while maintaining an irradiation energy of the CO₂ laser at a certain level. Therefore, the cooling rate of the V3D3 film can be controlled by controlling to reduce the output of the CO₂ laser after heating the V3D3 film at a predetermined temperature.

By controlling the cooling rate, a grain size of the V3D3 film can be controlled. That is, the grain size becomes small when the V3D3 film is rapidly cooled, and, on the other hand, the grain size becomes large when the V3D3 film is gradually cooled. Therefore, the density of the V3D3 film can be changed by varying the cooling rate of the V3D3 film. Additionally, the dielectric constant of the V3D3 film can be decreased by decreasing the density of the V3D3 film. Further, a mechanical strength can also be improved by controlling the grain size of the V3D3 film in a similar manner as a phenomenon of transformation from an austenitic structure into a martensitic structure in steel quenching.

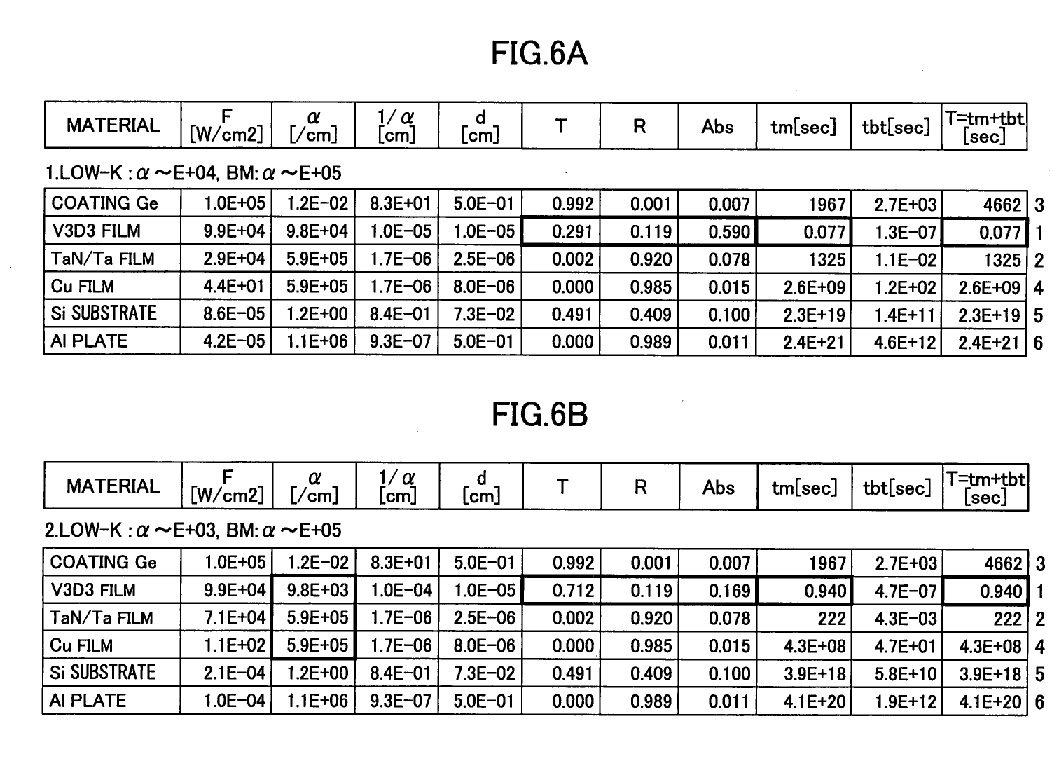

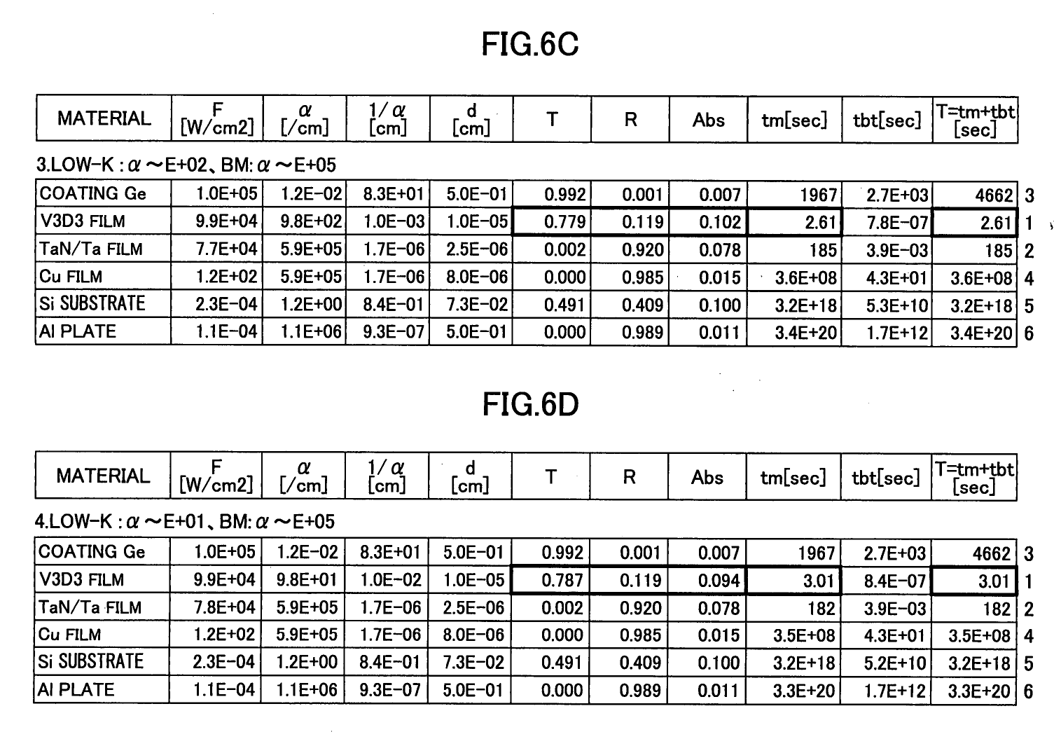

Here, results of calculation of a melting time of the V3D3 film when irradiating a CO₂ laser light of a wavelength of 9.6 μm-10.6 μm onto the V3D3 film are shown in FIGS. 6A through 6D. It was assumed that the V3D3 film is formed on a TaN film or a Ta film, and the TaN film or the Ta film is formed on a Cu film. The thickness of V3D3 film was set to 0.1 μm, the thickness of the TaN film or Ta film was set to 250 Å, and the thickness of the Cu film was set to 800 Å. Additionally, it was assumed that the above-mentioned films are formed on a silicon substrate having a thickness of 840 μm, and the silicon substrate is placed on an aluminum plate having a thickness of 5 mm. Moreover, it was assumed that the transparent window is formed of germanium (Ge) with surface coating. Moreover, it was assumed that the energy density of CO₂ laser light is 1×10⁵ W/cm².

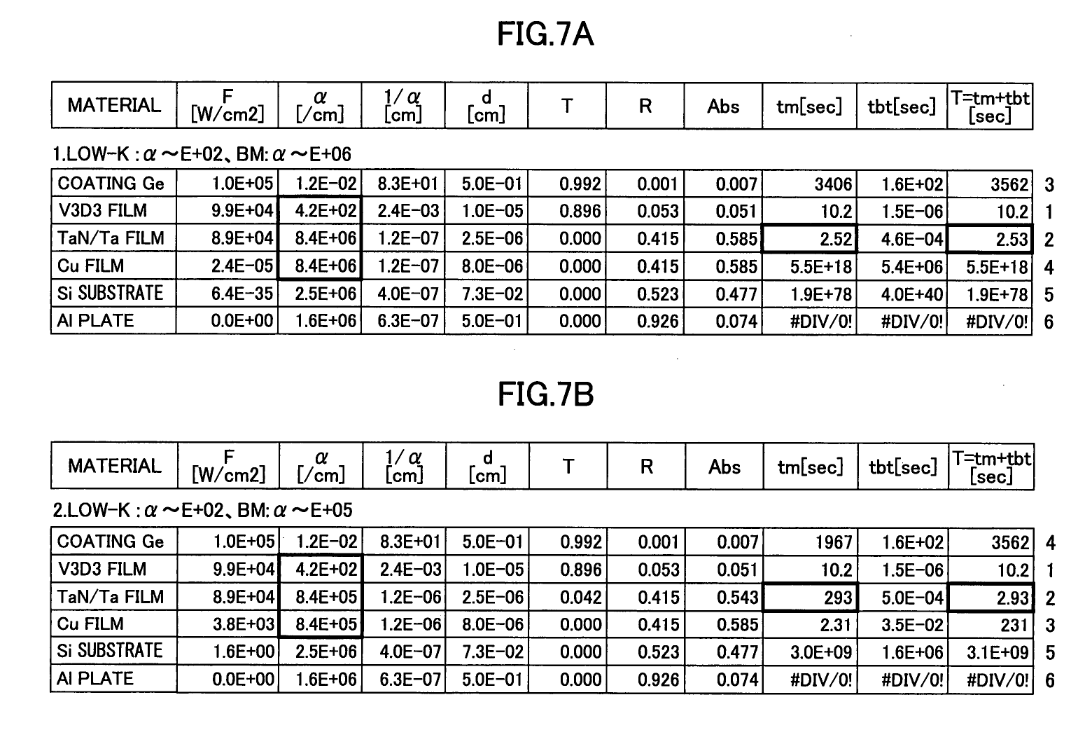

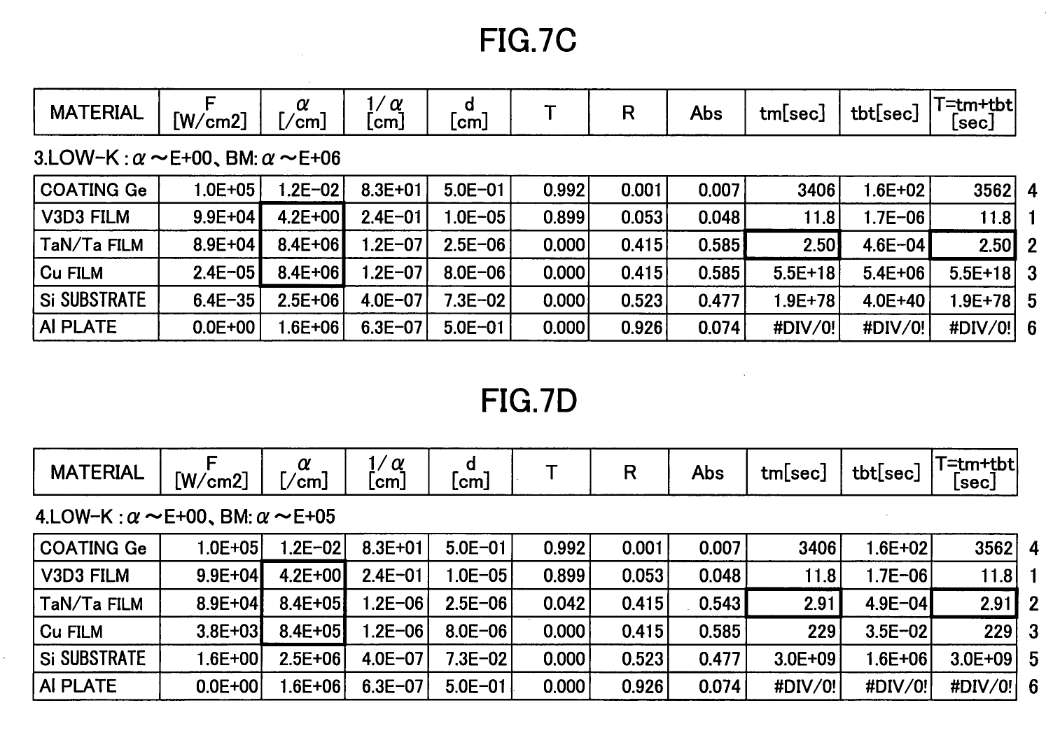

In FIGS. 6A through 6D, F represents an energy applied to the film or layer concerned; a represents an absorption factor; 1/α represents an absorption length; d represents a length (thickness) of the film or layer concerned; T represents a transmittance which is a non-dimensional number; R represents a reflectance which is a non-dimensional number; Abs represents an absorbance which is a non-dimensional number; tm represents a time period from an initial moment until a surface of the film or layer concerned is melted, which considers a heat transfer effect; tbt represents a time period from the time tm until a bottom surface of the film or layer concerned is melted; and T represents a sum of the time tm and the time tbt. Additionally, each number shown in the rightmost position of the figures represents an order of melting. That is, the number 1 indicates that the film or layer concerned is melted first, the number 2 indicates that the film or layer concerned is melted second, and so on. It should be noted that the same applies to FIGS. 7A through 7D, FIGS. 9A through 9D and FIGS. 10A through 10D mentioned later.

In the example shown in FIGS. 6A through 6D, a calculation of the melting time of each layer was performed in cases where the absorption factor α of the V3D3 film, which is a low-k film, is set to 9.8×10⁴/cm, 9.8×10³/cm, 9.8×10²/cm, and 9.8×10/cm. As a result of the calculation, it was found that the V3D3 film is melted for a time considerably shorter than that of other parts whether the absorption factor α is at any value of the above-mentioned values. For example, even in the case where the value of the absorption factor α of the V3D3 film was set to a small value such as 9.8×10/cm, the melting time of the V3D3 film was 3.01 seconds, while the melting time of the TaN film or the Ta film, which is an underlying layer of the V3D3 film, was 182 seconds.

Therefore, it was confirmed that the V3D3 film can be selectively heated while maintaining temperatures of other parts by projecting a CO₂ laser light onto the V3D3 film in the BEOL structure.

As mentioned above, by using the heat treatment apparatus according to the present invention, a low-dielectric film alone can be selectively heated by irradiating a light having a wavelength where an absorption factor of the low-dielectric film is extremely large and the cooling rate can be controlled. Thereby, modification of a material can be performed so as to provide a reduction in a dielectric constant or an improvement in a mechanical strength of a low-dielectric film (low-k film) such as a V3D3 film in the BEOL structure in a semiconductor structure such as a MOS transistor.

Although the material modification of a low-dielectric film according to selective heating and cooling can be performed by the heat treatment apparatus using the CO₂ laser as shown in FIG. 2, the light source is not limited to the laser, and the selective heating can be performed by infrared irradiation by an infrared lamp (IR lamp). That is, instead of the heat treatment apparatus shown in FIG. 2, the heat treatment apparatus shown in FIG. 4, which uses infrared lamps such as ceramic-coating lamps (wave length of 2-11 μm) as a lamp light source, can also be used. In this case, alumina (Al₂O₃) may be used as a material to form the transparent window 4. Although the optical transmission wavelength of alumina is 0.15 μm-6.0 μm and the wavelength range of the transmissible light is narrower than that of germanium, alumina can be used without problem since the infrared lamp light has an energy density lower than that of the CO₂ laser light.

An infrared light is projected from the infrared lamps onto a low-dielectric layer film in a transistor structure so as to heat the low-dielectric film, and, thereafter, the low-dielectric film is cooled while decreasing the irradiation energy of the infrared light. Thereby, an effect can be obtained the same as the effect, which is obtainable by the selective heating and cooling achieved by the above-mentioned laser light irradiation. By using the infrared lamps as a light source, the heat treatment apparatus can be manufactured at a cost lower than the case where a laser source is used. Moreover, by using the transparent window made of alumina, the manufacturing cost of the heat treatment apparatus can be reduced further.

2) Example of modifying a material by heat treatment of a barrier metal film while maintaining a surrounding area at a low temperature:

In the BEOL process of a semiconductor manufacturing process such as a transistor manufacturing process, a transistor structure has already been formed, as mentioned above. Thus, when applying a heat treatment in the BEOL process, it is preferable to heat only an object material to be heated while maintaining other materials at a relatively low temperature so that the transistor structure is not influenced by the heat treatment.

In a layer structure (hereinafter, referred to as BEOL structure) formed in the BEOL process, an attempt has been made to form an interlayer insulating layer by a low-dielectric material (low-k material) so as to achieve a high-speed operation of a transistor. Additionally, a TaN film or a Ta film is formed as a barrier metal film between the interlayer insulating layer (low-dielectric film) and a wiring layer.

In such a BEOL structure, there is a demand for improving adhesion between the barrier metal film and the low-dielectric film. Here, it was found that a chemical reaction occurs at an interface between the barrier metal film and the low-dielectric film when a portion including the interface is heated after formation of the barrier metal film and the low-dielectric film, and such a chemical reaction cause an improvement in adhesion between the barrier metal film and the low-dielectric film.

Therefore, there is a demand of selectively heating an upper layer part of the barrier metal film near the interface between the barrier metal film and the low-dielectric film and a lower layer part of the low-dielectric film near the interface between the barrier metal film and the low-dielectric film so as to cause a chemical reaction at the interface. Since the barrier metal film and the low-dielectric film are layers formed on the transistor structure already formed in the FEOL (Front End Of Line) process, it is required to selectively heat only a portion containing the interface between the barrier metal film and the low-dielectric film while maintaining the surrounding portions of the interlayer insulating layer at a low temperature so that the transistor structure is prevented from being destroyed.

Here, it was found that the TaN film and the Ta film used as a barrier metal film has a characteristic of absorbing an ultraviolet light. Thus, the barrier metal film such as a TaN film or a Ta film in the BEOL structure can be selectively heated by using an excimer laser (wavelength of 0.249 μm or 0.38 μm) as the laser source 5 in the heat treatment apparatus shown in FIG. 2. Accordingly, the interface between the barrier metal film and the low-dielectric film can be selectively heated to improve adhesion between the barrier metal film and the low-dielectric film.

Here, results of calculation of a melting time of each layer when projecting an ultraviolet laser light having a wavelength of 0.3 μm onto a low-dielectric film (V3D3) film in the BEOL structure are shown in FIGS. 7A through 7D. It was assumed that the V3D3 film is formed on a TaN film or a Ta film as a barrier metal film, and the TaN film or the Ta film is formed on a Cu film. It was assumed that a thickness of the V3D3 film is set to 0.1 μm, a thickness of the TaN film or Ta film is set to 250 Å, and a thickness of the Cu film is set to 800 Å. Moreover, it was assumed that the above-mentioned films are formed on a silicon substrate having a thickness of 730 μm, and the silicon substrate was placed on an aluminum plate having a thickness of 5 mm. Moreover, it was assumed that the transparent window is made of calcium fluoride (CaF₂). Further, it was assumed that an energy density of the ultraviolet laser light is 1×10⁵ W/cm².

In the example shown in FIGS. 7A through 7D, a melting time of each layer was calculated in cases where the absorption factor α of the V3D3 film as a low-dielectric film is set to 4.2×10⁴/cm and 4.2/cm and the absorption factor α of the TaN film or the Ta film as a barrier metal film is set to 8.4×10⁶/cm and 8.4×10⁵/cm. According to the results of calculation, it was found that the TaN film or the Ta film as a barrier metal film is melted within a time considerably shorter than that of other portions in any cases where the absorption factor α of the V3D3 film and the absorption factor α of the TaN film or the Ta film are set to one of the above mentioned values.

For example, when the value of the absorption factor of the V3D3 film is set to 4.2×10²/cm and the value of the absorption factor of the TaN film or the Ta film is set to 8.4×10⁶/cm, the surface (interface) of the TaN film or the Ta film is melted in 2.5 seconds, while a time until the upper layer V3D3 film is melted is 10.2 seconds. Thus, the TaN film or the Ta film can be selectively heated much faster than the upper layer V3D3 film so as to selectively heat a portion including the interface between the V3D3 film and the TaN film or the Ta film.

As mentioned above, using the heat treatment apparatus according to the present invention, a barrier metal film can sorely and selectively radiation-heated by irradiating a light having a wavelength at which the absorption factor of the barrier metal film is extremely large. Thus, a material modification can be performed such as an improvement in adhesion between a barrier metal film such as a TaN film or a Ta film in a BEOL structure in a semiconductor structure such as a MOS transistor and a low-dielectric film such as a V3D3 film formed on the barrier metal film.

Although the above-mentioned selective heating of a barrier metal film can be performed by the heat treatment apparatus shown in FIG. 2, which uses an ultraviolet laser as a light source, the light source is not limited to the laser and an ultraviolet lamp (UV lamp) may be used to irradiate an ultraviolet light. That is, instead of the heat treatment apparatus shown in FIG. 2, the heat treatment apparatus shown in FIG. 4, which uses ultraviolet lamps such as an arc lamp (wavelength of 0.2-1.2 μm) or a metal halide lamp as a light source, may be used. In such a case, it is preferable to use calcium fluoride (CaF₂) as a material to form the transparent window 4.

That is, a barrier metal film under a low-dielectric film in a BEOL structure in a transistor structure is selectively heated by projecting an ultraviolet light from an ultraviolet lamp onto the low-dielectric film, and, thereafter, cooling is performed while controlling the irradiation energy. Thereby, an effect can be obtained the same as the effect, which is obtainable by the selective heating and cooling achieved by irradiation of the laser light. By using the ultraviolet lamps as a light source, a relatively inexpensive heat treatment apparatus can be achieved than using a laser as a light source.

A description will now be given of other examples of the selective heating of a film or layer according to the present invention.

The above-mentioned selective heating of a low-dielectric film and a barrier metal film in the BEOL structure is applicable to a layer or film of the FEOL (Front End Of Line) structure formed in a semiconductor manufacturing process.

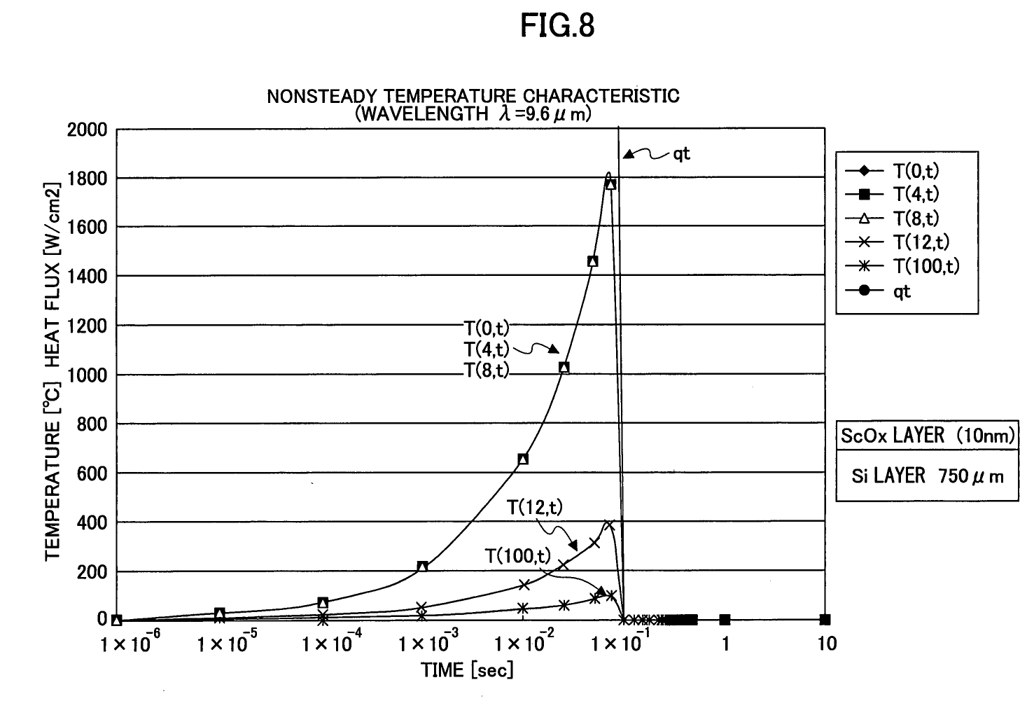

As an example of the temperature calculation according to the above-mentioned equation (2), a temperature rise in a layer structure in which a screen oxide film (hereinafter, referred to as SC—Ox film) is formed on a silicon (Si) substrate, when heating the layer structure by projecting a CO₂ laser onto the layer structure was calculated using the equation (2). FIG. 8 is a graph showing the results of the calculation. It was assumed that a thickness of the silicon substrate is set to 750 μm, and a thickness of the SC—Ox film is set to 10 nm. Additionally, the calculation was made by setting a heat flux generated by irradiation of the CO₂ laser to 5×10⁴ W/cm², and an irradiation time was set to 0.1 seconds. It should be noted that the sign “qt” in the graph of FIG. 8 indicates a heat flux directing from a surface to inside of the SC—Ox film, and it can be appreciated from the graph that the heat flue rapidly decreases from a time 0.1 second after stopping a laser projection. In the graph of FIG. 8, T(0,t) represents a temperature of the surface of the SC—Ox film, and T(4,t), T(8,t), T(12,t) and T(100,t) represent temperatures at positions 4 nm, 8 nm, 10 nm and 100 nm distant from the surface, respectively. That is, T(0,t), T(4,t) and T(8,t) represent temperatures inside the SC—Ox film. On the other hand, T(12,t) represents a temperature of the silicon substrate at a position slightly away from a boundary between the SC—Ox film and the silicon substrate, and T(100,t) represents a temperature of the silicon substrate at a position sufficiently away from the boundary.

It can be appreciated from the graph of FIG. 8 that the temperatures T(0,t), T(4,t) and T(8,t)) inside the SC—Ox film rise sharply after the laser irradiation time exceeds 1×10⁻² seconds and become higher than a melting point (1,690° C.) of the SC—Ox film. Thereafter, the temperatures sharply fall just before 1×10⁻¹ seconds. On the other hand, the temperatures T(12,T) and T(100,t) of the silicon substrate reach temperatures far lower than the melting point (1,414° C.) of the silicon substrate. Therefore, in the example shown in FIG. 8, the SC—Ox film alone an be selectively heated and melted while maintaining the silicon substrate as an underlying layer at a relatively low temperature (below the melting point).

A description will be given below of examples of material modification of a film or layer in a layer structure formed in the FEOL process.

1) Example of material modification to reduce grain size by a large temperature falling rate:

In a semiconductor manufacturing process such as a transistor manufacturing process, a spike anneal is applied with a purpose of activating doped impurities so as to form a ultra shallow junction (USJ) in an initial part (FEOL: Front End Of Line) of a process of forming thin films on a wafer. Additionally, rapid temperature rising and falling such as flash lamp anneal may be applied.

In the activation of the doped impurities, it is possible that a USJ size (thickness of the USJ) is increased due to a transient accelerated diffusion in which ion-implanted impurity atoms have large velocity. Therefore, it is needed to perform a heat treatment with a rapid heating and cooling while preventing the fine structure from being deteriorated so that the ion-implanted impurity atoms are changed from interstitial atoms to lattice atoms, which results in a stably functioning junction layer.

In order to realize such a heat treatment with rapid heating and cooling, the conventional semiconductor manufacturing apparatus (heat treatment apparatus) uses a heat treatment method in which a large part of a process chamber is heated so as to rapidly heat an entire silicon (Si) wafer. However, a layer which needs material modification is a very small part of the entire wafer, and it is no an efficient way to heat a large part of the wafer containing the layer to be heated. Conventionally, there is no concept or attempt to selectively heat a layer alone, which layer requiring the material modification. Moreover, although many attempts have been suggested to raise a temperature rising rate in the conventional heat treatment apparatus, there are less number of attempts to increase a cooling rate so as to achieve rapid cooling. There only is an experimental example relating to a UV laser anneal.

Here, the technique of selective heating and the improvement in the rate of heating and cooling are closely related with each other. If the selective heating limited to a specific layer is achieved, a heat capacity of the object to be heated can be made small. However, since selective heating cannot be performed in the conventional technique, a hardware having a large heat capacity such as a process chamber must be heated and the cooling must be performed according to a heat transfer characteristic of the process chamber. For this reason, it has not been achieved to perform a heat treatment (anneal) which activates the junction layer while controlling distribution of impurities implanted during formation of transistors within a shallow layer.

Thus, according to the present invention, a silicon oxide film is selectively heated by irradiating a CO₂ laser onto the silicon oxide film using the heat treatment apparatus shown in FIG. 2. That is, a CO₂ laser (wavelength of 9.6-10.6 μM) having a wavelength corresponding to a wavelength at which the silicon oxide film formed on a wafer has a large optical absorption factor is irradiated onto the silicon oxide film. Thereby, only the silicon oxide film, which is an object to be heated, can be selectively heated and melted. It should be noted that as an oxide film to which the selective heating by the CO₂ laser is applicable, there are a low-dielectric film (low-k film) having an Si—O bond and a high-dielectric film (high-k film) such as an SiON film or an HfO film.

After the silicon oxide film is melted, the melted silicon oxide film is cooled at a large cooling rate by rapidly reducing irradiation energy of the CO₂ laser. That is, since only the silicon oxide film is selectively heated, parts surrounding the silicon oxide film are still at a low temperature and the heat of the silicon oxide film rapidly spreads into the surrounding parts, which rapidly cools the silicon oxide film itself. The above-mentioned selective heating and rapid cooling are applied to a shallow junction layer formed between a source and a drain under a screen oxide film so as to activate the shallow junction layer without diffusion of impurities. Since diffusion of impurities can be controlled not only in a vertical direction (direction of thickness) of the shallow junction layer but also in a transverse direction, a junction layer suitable for forming a fine MOS transistor structure can be formed.

Moreover, since rapid cooling can be achieved, crystallization and crystal growth of a gate oxide film (for example, an HfSiON film) can be controlled. Thereby, a leak current which flows along a grain boundary can be reduced, which result in formation of a high performance transistor.

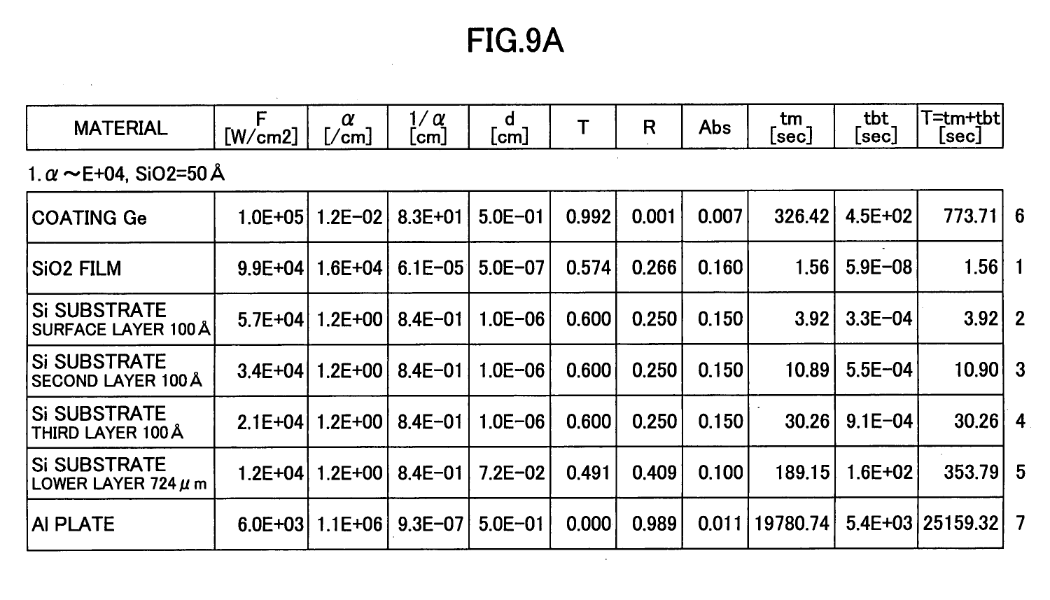

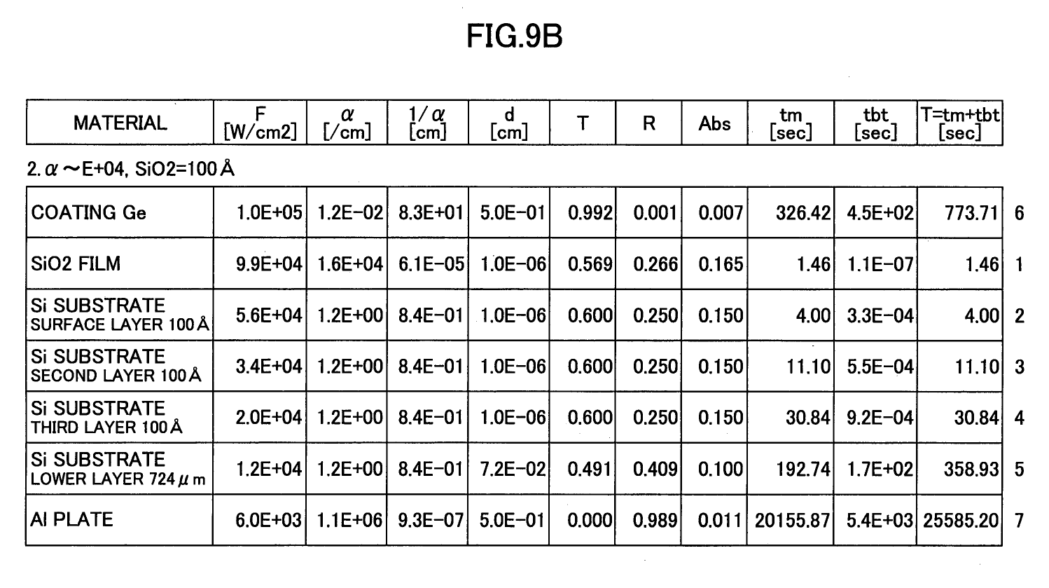

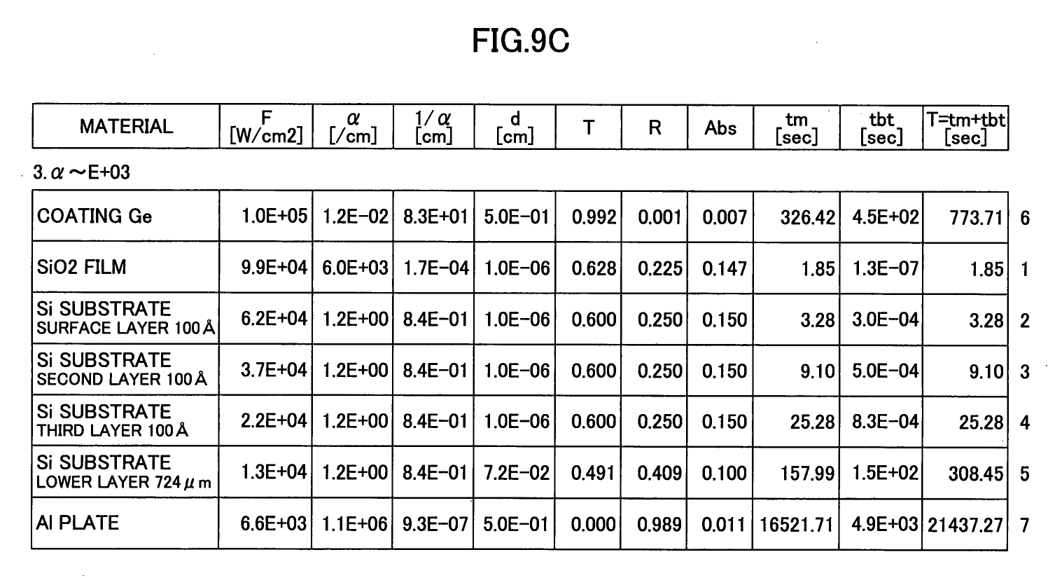

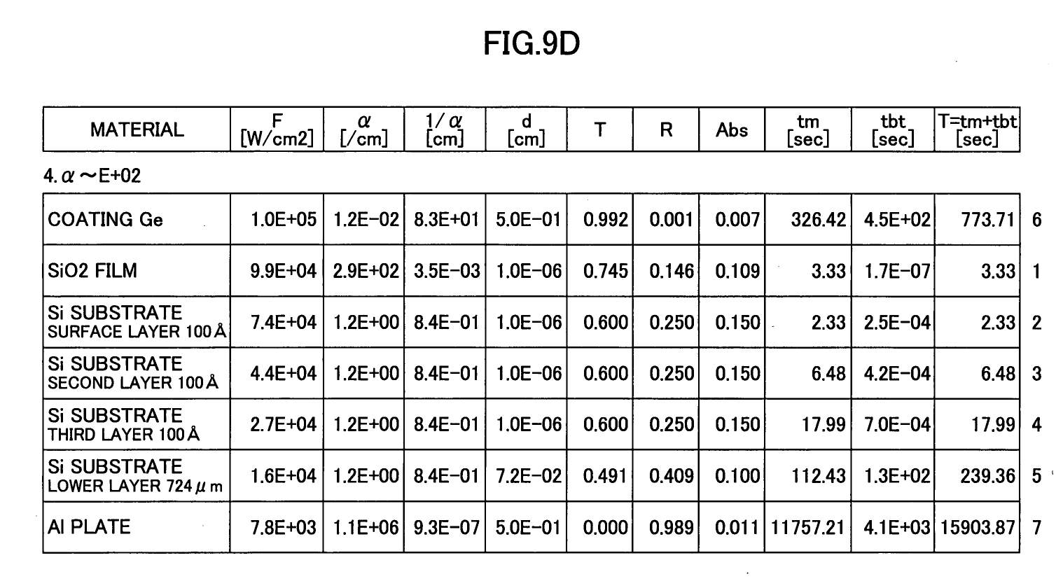

FIGS. 9A through 9D are illustrations showing results of calculation of a melting time when a CO₂ laser having a wavelength of 9.6-10.6 μm is irradiated onto a screen oxide film (SiO₂ film). The melting time of the screen oxide film and the melting time of other layers were obtained according to the calculation method in which a time t until a film of an object material is melted is defined as t=tm+tbt.

It was assumed that the screen oxide film is formed on a silicon (Si) substrate, and the silicon substrate is placed on an aluminum plate having a thickness of 5 mm. It was assumed that the silicon substrate has a surface layer having a thickness of 100 Å, which is measured from the interface between the screen oxide film and the silicon substrate, a second layer having a thickness of 100 Å and a third layer having a thickness of 100 Å so as to calculate a melting time of each layer. Moreover, it was assumed that the transparent window is formed of germanium (Ge) with surface coating. Moreover, it was assumed that an energy density of CO₂ laser light is set to 1×10⁵ W/cm².

If the absorption factor α of the SiO₂ film is set to 1.6×10⁴/cm, the melting time until the SiO₂ film is melted is shorter than a time until other layer is melted when the thickness of the SiO₂ film is either 50 Å or 100 Å. Additionally, the melting time of the SiO₂ film is less than a half of the melting time of the surface layer of the silicon substrate. Thus, it was confirmed that the SiO₂ film alone can be selectively melted.

Moreover, even when the absorption factor α of the SiO₂ film is set to 6.0×10³/cm and a film thickness of the SiO₂ film is set to 100 Å, the melting time until the SiO₂ film is melted is shorter than the melting time of other layers. Additionally, the melting time of the SiO₂ film is less than a half of the melting time of the surface layer of the silicon substrate. Thus, it was confirmed that the SiO₂ film alone can be selectively melted.

Furthermore, although the surface layer of the silicon substrate is melted faster than the SiO₂ film when the absorption factor α of the SiO₂ film is set to 6.0×10³/cm and a film thickness of the SiO₂ film is set to 100 Å, the melting time until the SiO₂ film is melted is about a half of the melting time of the second layer of the silicon substrate. Thus, it was confirmed that the SiO₂ film alone can be selectively melted.

As the result of calculation of the melting time of the SiO₂ film and the melting time of the silicon substrate as an underlying layer as mentioned above, it was found that the SiO₂ film can be selectively melted even though the condition of the SiO₂ film is changed.

As mentioned above, using the heat treatment apparatus according to the present invention, a heat treatment such as a laser anneal can be efficiently performed in the formation of a semiconductor structure such as a MOS transistor by selectively radiation-heating an oxide film by irradiating a light having a wavelength at which the absorption factor of the oxide film is extremely large and cooling the oxide film at a large cooling rate. Moreover, according to the selective heating and cooing achieved by the present invention, a shallow junction layer suitable for a fine structure such as a MOS transistor structure can be easily formed.

Although the material modification of a silicon oxide film according to selective heating and cooling can be performed by the heat treatment apparatus using the CO₂ laser as shown in FIG. 2, the light source is not limited to the laser, and the selective heating can be performed by irradiation of an infrared light by an infrared lamp (IR lamp). That is, instead of the heat treatment apparatus shown in FIG. 2, the heat treatment apparatus shown in FIG. 4, which uses infrared lamps such as ceramic-coating lamps (wave length of 2-11 μm) as a lamp light source, can also be used. In this case, alumina (Al₂O₃) may be used as a material to form the transparent window 4. Although the optical transmission wavelength of alumina is 0.15 μm-6.0 μm and the wavelength range of the transmissible light is narrower than that of germanium, alumina can be used without problem since the infrared lamp light has an energy density lower than that of the CO₂ laser light.

An infrared light is projected from the infrared lamps onto a screen oxide film or a gate oxide film in a transistor structure so as to heat the oxide film, and, thereafter, the oxide film is cooled while decreasing the irradiation energy of the infrared light. Thereby, an effect can be obtained the same as the effect, which is obtainable by the selective heating and cooling achieved by the above-mentioned laser light irradiation. By using the infrared lamp as a light source, the heat treatment apparatus can be manufactured at a cost lower than the case where a laser source is used. Moreover, by using the transparent window made of alumina, the manufacturing cost of the heat treatment apparatus can be reduced further.

2) Example of material modification to cause segregation by a large temperature falling rate:

Conventionally, when annealing an entire FEOL structure of a MOS transistor by a heat treatment apparatus, it is not possible to modify only a gate oxide film layer. Although many techniques have been suggested to control a heating rate (temperature-rising rate), there has been no technique suggested to control even a cooling rate (temperature-falling rate). That is, the conventional heat treatment apparatus merely heats and cools an entire interior of a process chamber including an entire wafer, and it is not possible to selectively heat and cool an SiON layer, which is a gate oxide film requiring material modification. Accordingly, the material layer to be heated is heated together with the entire wafer, and the material layer to be heated is also cooled by cooling of the entire wafer. Therefore, the cooling rate of the material layer to be heated is dominated by the cooling rate of the entire wafer, which prevents the material layer form being rapidly cooled.

As mentioned above, according the heat treatment method using the conventional heat treatment apparatus, the gate oxide film can be heated at a predetermined temperature so as to melt the gate oxide film, but the melted gate oxide film is solidified at a gentle or moderate cooling rate. For this reason, it is difficult to change a distribution depth of nitrogen atoms in the SiON layer as a gate oxide film, and the distribution depth is maintained unchanged. If nitrogen atoms can be intentionally moved to the outermost surface layer, it is possible to reduce a leak current from the gate oxide film. However, it is necessary to cool rapidly the melted gate oxide film to quickly solidify the melted gate oxide film so as to cause the nitrogen atoms to move to the outermost surface layer (to cause the nitrogen atoms segregate in the outermost surface layer).

Thus, using the heat treatment apparatus according to the present invention, a CO₂ laser having a wavelength at which the optical absorption factor of the gate oxide film is large is irradiated onto the wafer (that is, the gate oxide film) so as to heat and melt the gate oxide film. Thereafter, the melted gate oxide film is solidified while controlling a cooling rate by reducing laser irradiation energy. That is, by controlling an output of the laser source 5 by the power controller 8 shown in FIG. 2, the irradiation energy of the CO₂ laser is controlled so that the melted SiON layer is solidified from a lower layer side to an upper layer side. Thereby, the nitrogen atoms can be caused to segregate at a high concentration in the outermost surface layer during the solidification of the melted gate oxide film. Thus, while maintaining a good condition of the interface of the underlying layer, a leak current of the gate oxide film (SiON layer) of the transistor structure can be reduced and also diffusion (or penetration) of impurities of a gate electrode polysilicon into the SiON layer can be suppressed.

In the above-mentioned example, the gate oxide film is selectively heated and the cooling rate is controlled so as to cause the nitrogen atoms to intentionally segregate in the gate oxide film to obtain a desired effect. Since the cooling can be performed at a large cooling rate by stopping the laser irradiation after heating, the cooling rate can be controlled by cooling while performing laser irradiation at a laser power reduced to an appropriate level, and also controlled so that the solidification occurs from a lower layer side.

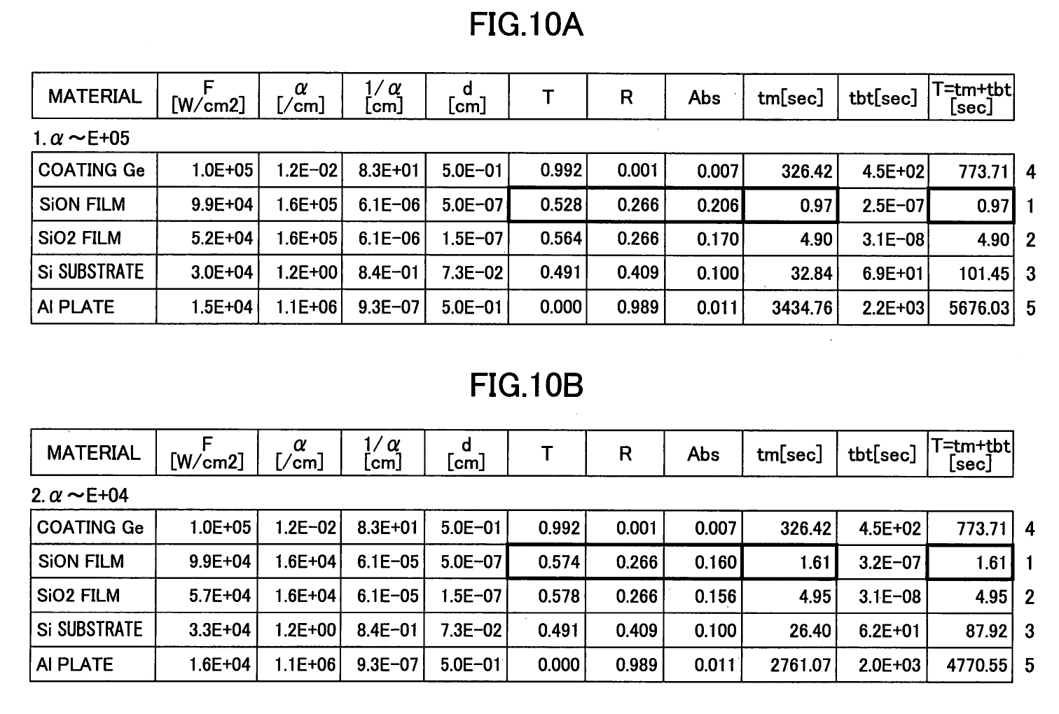

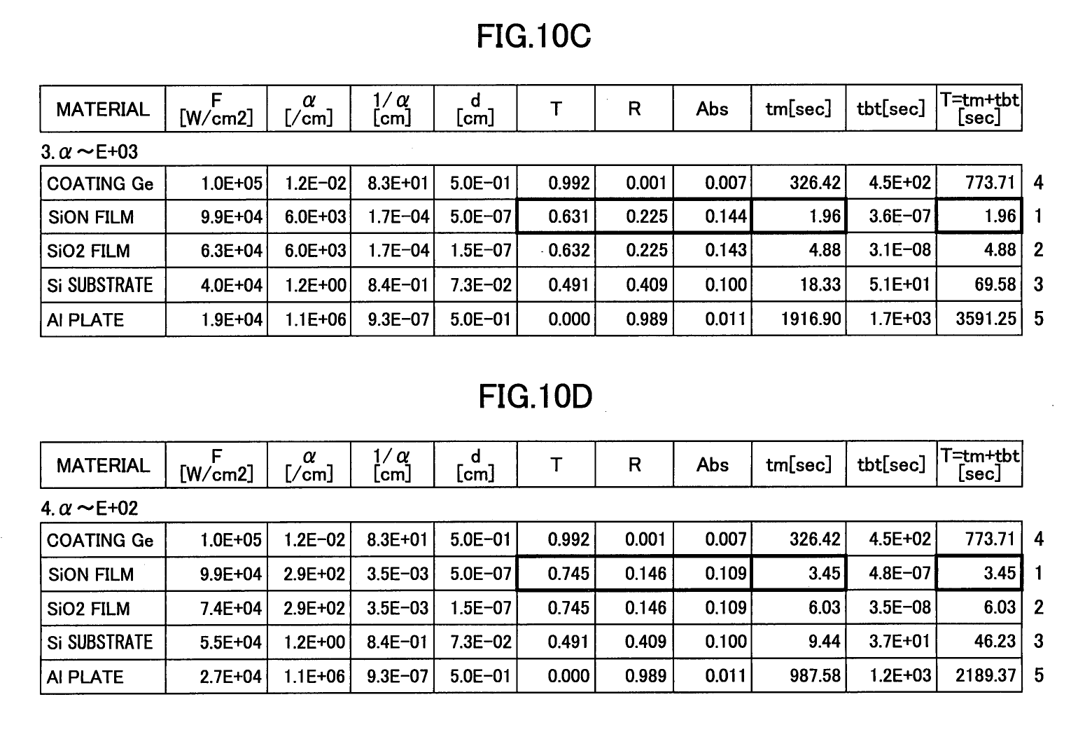

FIGS. 10A through 10D show results of calculation of a melting time when a CO₂ laser of a wavelength of 9.6 μm-10.6 μm is irradiated onto a gate oxide film (SiON film). The melting time of the gate oxide film and the melting time of other layers were calculated according to a calculation method in which a time t until the film of the object material is melted is defined as t=tm+tbt.

When performing the calculation, it was assumed that the SiON film is formed on an SiO₂ film that is formed on a silicon (Si) substrate, and the silicon substrate is placed on an aluminum plate having a thickness of 5 mm. It was assumed that a thickness of the SiON film is 50 Å, and a thickness of the SiO₂ film is 150 Å. It was assumed that a thickness of the silicon substrate is set to 730 μm. Further, it was assumed that the transparent window is formed of germanium (Ge) with surface coating. Moreover, it was assumed that energy density of the CO₂ laser light is se to 1×10⁵ W/cm².

As shown in FIGS. 10A through 10D, when the absorption factor α of the SiON film is set to 1.6×10⁵/cm, 1.6×10⁴/cm and 6.0×10³/cm, the time until the SiON film is melted is shorter than the time until other layers are melted in either case, and the melting time of the SiON film is about a half of the time until the SiO₂ film as an underlying layer is melted. Thus, it was confirmed that the SiON film alone can be selectively melted.

Moreover, even when the absorption factor α of the SiON film is set to 2.9×10²/cm, the time until the SiON film is melted is shorter than the time until other layers are melted and is about a half of the time until the SiO₂ film as an underlying layer is melted. Thus, it was confirmed that the SiON film alone can be selectively melted.

As mentioned above, according to the calculation of the melting time of the SiON film and the melting time of the SiO₂ film as an underlying layer, it was found that the SiON film can be selectively melted even though the condition of the SiON film is changed.

Although the material modification of a gate oxide film according to selective heating and cooling can be performed by the heat treatment apparatus using the CO₂ laser as shown in FIG. 2, the light source is not limited to the laser, and the selective heating can be performed by irradiation of an infrared light by an infrared lamp (IR lamp). That is, instead of the heat treatment apparatus shown in FIG. 2, the heat treatment apparatus shown in FIG. 4, which uses infrared lamps such as ceramic-coating lamps (wave length of 2-11 μm) as a lamp light source, can also be used. In this case, alumina (Al₂O₃) may be used as a material to form the transparent window 14.

An infrared light is projected from the infrared lamps onto a gate oxide film in a transistor structure so as to heat the gate oxide film, and, thereafter, the gate oxide film is cooled while decreasing the irradiation energy of the infrared light. Thereby, an effect can be obtained the same as the effect, which is obtainable by the selective heating and cooling achieved by the above-mentioned laser light irradiation. By using the infrared lamp as a light source, the heat treatment apparatus can be manufactured at a cost lower than the case where a laser source is used. Moreover, by using the transparent window made of alumina, the manufacturing cost of the heat treatment apparatus can be reduced further.

The present invention is not limited to the specifically disclosed embodiments, and variations and modifications may be made without departing from the scope of the present invention.

The present application is based on Japanese priority applications No. 2003-166809 filed Jun. 11, 2003, and No. 2003-173434 filed Jun. 18, 2003, the entire contents of which are hereby incorporated by reference.

What is claimed is:

1. A semiconductor manufacturing apparatus for applying a heat treatment to a heating material to be heated by radiation-heating by irradiating a light onto the processing object, the semiconductor manufacturing apparatus comprising:
a process chamber configured to accommodate a processing object containing said heating material;
a transparent window provided as a part of an outer wall of said process chamber;
a light source that generates the light so as to irradiate the light onto said heating material through said transparent window; and
a controller that controls an output of said light source,
wherein said heating material is a material to form a layer formed in a wiring process after a semiconductor structure is formed in a semiconductor manufacturing process;
the light irradiated by said light source has a specific wavelength at which an optical absorption factor of said heating material is larger than at other wavelengths; and
said transparent window is formed of a material that passes therethrough the light having the specific wavelength.

2. The semiconductor manufacturing apparatus as claimed in claim 1, wherein said light source is a laser source that outputs a laser light, and said semiconductor manufacturing apparatus further comprises an optical system that direct the laser light so that the laser light is irradiated onto said heating material in a linear form.

3. The semiconductor manufacturing apparatus as claimed in claim 2, wherein said laser source is an infrared laser, and said heating material is a low-dielectric film formed in the wiring process of the semiconductor manufacturing process.

4. The semiconductor manufacturing apparatus as claimed in claim 3, wherein said infrared laser is a CO₂ laser, and said transparent window is formed of germanium.

5. The semiconductor manufacturing apparatus as claimed in claim 1, wherein said light source is an infrared lamp that outputs an infrared light, and said heating material is a low-dielectric film formed in the wiring process of the semiconductor process.

6. The semiconductor manufacturing apparatus as claimed in claim 2, wherein said laser source is an ultraviolet laser, and said heating material is a barrier metal film formed in the wiring process of the semiconductor manufacturing process.

7. The semiconductor manufacturing apparatus as claimed in claim 6, wherein said ultraviolet laser is an excimer laser, and said transparent window is formed of calcium fluoride.

8. The semiconductor manufacturing apparatus as claimed in claim 1, wherein said light source is an ultraviolet lamp that outputs an ultraviolet light, and said heating material is a barrier metal film formed in the wiring process of the semiconductor manufacturing process.

9. A heat treatment method used for a heat treatment applicable to a film formed in a wiring process of a semiconductor manufacturing process, the heat treatment method comprising:
irradiating a light having a wavelength that corresponds to an optical absorption wavelength of said film formed in the wiring process of the semiconductor manufacturing process so as to selectively heat said film with respect to surrounding parts; and
cooling said heated film by heat transfer to the surrounding parts by controlling an intensity of the light irradiated onto said film.

10. The heat treatment method as claimed in claim 9, wherein said film is a low-dielectric material having an Si—O bond, said light is a CO₂ laser light, and a dielectric constant and a mechanical strength of said low-dielectric film are varied by selectively heating said low-dielectric film.

11. The heat treatment method as claimed in claim 10, wherein said low-dielectric film is an SiOCH film.

12. The heat treatment method as claimed in claim 9, wherein said film is a barrier metal film formed between a low-dielectric film and a electrically conductive layer, said light is an ultraviolet laser light, and said barrier metal film is selectively heated, thereby improving adhesion between said barrier metal film and said low-dielectric film.

13. The heat treatment method as claimed in claim 12, wherein said barrier metal film is a TaN film or a Ta film, and said ultraviolet laser light is an excimer laser light.

14. A semiconductor manufacturing apparatus for applying a heat treatment to a heating material to be heated by radiation-heating by irradiating a light onto the processing object, the semiconductor manufacturing apparatus comprising:
a process chamber configured to accommodate a processing object containing said heating material;
a transparent window provided as a part of an outer wall of said process chamber;
a light source that generates the light so as to irradiate the light onto said heating material through said transparent window; and
a controller that controls an output of said light source,
wherein said light irradiated by said light source has a specific wavelength at which an optical absorption factor of said heating material is larger than at other wavelengths; and
said transparent window is formed of a material that does not absorb the light having the specific wavelength.

15. The semiconductor manufacturing apparatus as claimed in claim 1, wherein said light source is a laser source which outputs a laser light, and said semiconductor manufacturing apparatus further comprises an optical system that direct the laser light so that the laser light is irradiated onto said heating material in a linear form.

16. The semiconductor manufacturing apparatus as claimed in claim 15, wherein said laser source is an infrared laser, and said heating material is a silicon oxide film formed in an initial process of a semiconductor manufacturing process.

17. The semiconductor manufacturing apparatus as claimed in claim 16, wherein said infrared laser is a CO₂ laser, and said transparent window is formed of germanium.

18. The semiconductor manufacturing apparatus as claimed in claim 14, wherein said light source is an infrared lamp that outputs an infrared light, and said heating material is a silicon oxide film formed in an initial process of a semiconductor manufacturing process.

19. The semiconductor manufacturing apparatus as claimed in claim 18, wherein said transparent window is formed of Al₂O₃.

20. A heat treatment method used for semiconductor manufacturing, comprising:
irradiating a light having a wavelength that corresponds to an optical absorption wavelength of a heating material to be heated and formed in a wiring process of a semiconductor manufacturing process so as to selectively heat said heating object with respect to surrounding parts; and
cooling said heated heating material by heat transfer to the surrounding parts by controlling an intensity of the light irradiated onto said heating material.

21. The heat treatment method as claimed in claim 20, wherein said heating material is a silicon oxide film, and said light is a CO₂ laser light.

22. The heat treatment method as claimed in claim 21, wherein said heating material is a silicon oxide film, and said light is an infrared light output from an infrared lamp.

23. The heat treatment method as claimed in claim 20, wherein said heating material is melted by being selectively heated, and, in a subsequent cooling process, said melted heating material is rapidly cooled so that crystallization and crystal growth of said heating material are suppressed.

24. The heat treatment method as claimed in claim 20, wherein said heating material is melted by being selectively heated, and, in a subsequent cooling process, said melted heating material is rapidly cooled so that elements contained in said heating material segregate during solidification of said melted heating material.
